(19) United States
(12) Patent Application Publication
(10) Pub. No.: US 2015/0239435 A1
(43) Pub. Date: Aug. 27, 2015

(54) HEATING DEVICE FOR A VEHICLE WINDSCREEN WIPER, WINDSCREEN WIPER INCLUDING IT, AND METHOD OF ASSEMBLING SUCH A WINDSCREEN WIPER

(71) Applicant: ValeoSystémes d'Essuyage, Le Mesnil Saint Denis (FR)

(72) Inventors: Gérald Caillot, Cernay La Ville (FR); Vincent Izabel, Chilly Mazarin (FR); Jean-Michel Jarasson, Le Mesnil Saint Denis (FR)

(73) Assignee: VALEO SYSTEMES D'ESSUYAGE, Le Mesnil Saint Denis (FR)

(21) Appl. No.: 14/628,865

(22) Filed: Feb. 23, 2015

(30) Foreign Application Priority Data
Feb. 24, 2014 (FR) 1451451

(51) Int. Cl. B60S 1/38; H05K 13/04; H05B 3/03

(52) U.S. Cl. CPC B60S 1/3805; H05B 3/03; H05K 13/04; B60S 2001/3898

(57) ABSTRACT

A heating device includes an element forming a spline adapted to be mounted inside a longitudinal housing of a support element to form a spline, the housing being open upwardly via a longitudinal slot. A heating element is disposed on the element forming a spline and connected by electrically conductive means to an electrical connect disposed on an upper face of the spline. The heating element is disposed on a lower face of the element forming a spline and the electrically conductive means pass from the lower face to the upper face of the spline around one of the ends thereof.

The present invention concerns a heating device for a vehicle windscreen wiper and a windscreen wiper including it. It also concerns a method of assembling such a windscreen wiper.

The heating device in this kind of windscreen wiper includes a heating element integrated into the body of the windscreen wiper and extending over substantially all the length thereof. Thanks to the presence of this heating element, it is possible to melt ice or snow that might otherwise form or accumulate on the windscreen wiper during cold weather and that then impedes its proper operation. This can be even more of a nuisance if the windscreen wiper is provided with a manifold for distributing a washing liquid which, in the event that it freezes, in particular at the level of the distribution holes, prevents the liquid from escaping and can generally render the whole of the windscreen wiper too rigid.

The heating device of the windscreen wiper may include one or more resistive wires associated with one of the elements constituting the windscreen wiper. The resistive wire or wires generally extend or extends all along one of these constituent elements.

There is also known a heating device of this kind including a resistive film incorporated into the windscreen wiper. This windscreen wiper is of the flat type, often referred to as a flexible windscreen wiper or flat windscreen wiper.

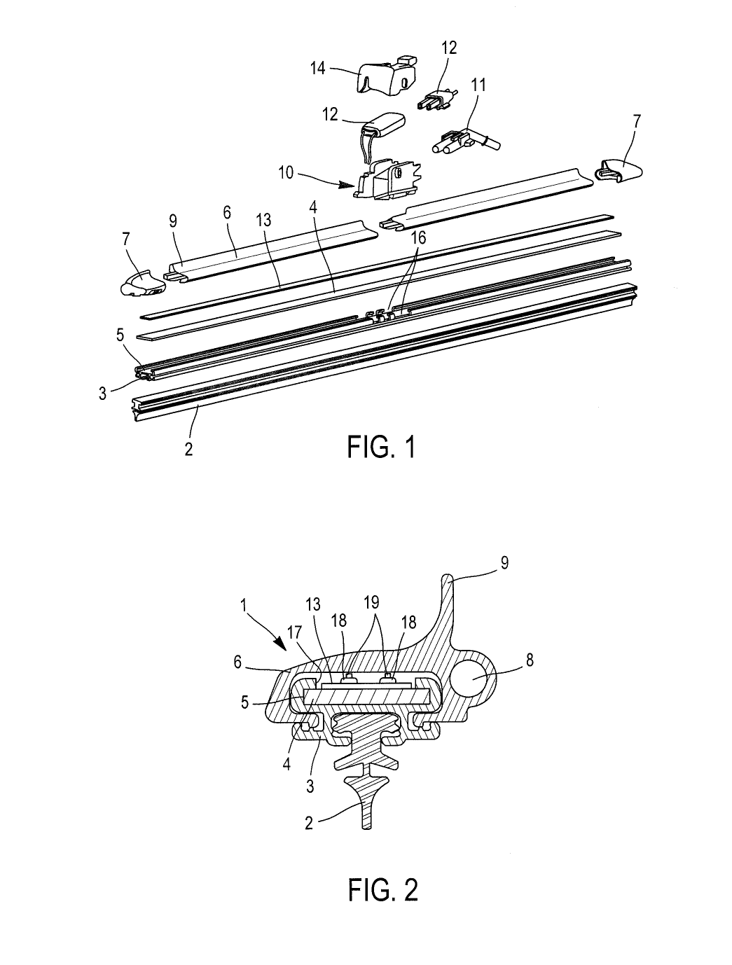

The constituent elements of this known windscreen wiper are shown in FIG. 1 and include, from the bottom upwards, a wiper blade 2, generally made of elastomer, fixed to an elongate support element 3, generally made of a semi-rigid plastic material, an element 4 having a longitudinal main axis and forming a spline disposed in a longitudinal housing 5 of the support element 3, and a cover element 6 clipped to the support element 3. These constituent elements are substantially the same length and during assembly of the windscreen wiper an end cap 7 is fixed to each end thereof.

FIG. 2 shows a section of such a windscreen wiper when assembled. The cover element 6 constitutes an accessory which in this example further includes over part of its length a manifold 8 for spraying a washing liquid. The manifold 8 is provided with spray holes (not represented). This accessory advantageously includes an aerodynamic deflector 9 intended to press the wiper blade 2 more strongly against a vehicle window (not shown). The cover element 6 may alternatively include two spray manifolds, one along each side of the cover element.

The cover element 6 of the windscreen wiper 1 is in two parts of substantially the same length and connected to each other by way of a mechanical connector 10 that accommodates a hydraulic connector 11 for the washing liquid, together with an electrical connector 12 connected to a heating element 13 in the form of a resistive film that is incorporated into the windscreen wiper.

The mechanical connector 10 is closed outwardly by a cap forming a connecting member 14 connecting it to an actuating arm (not represented) via an articulation (not represented). A wiping device is therefore formed by the windscreen wiper 1, this actuating arm, and a motor (not represented) for driving the latter in oscillation.

The support element 3 includes in a central zone two lateral cut-outs 16 disposed facing each other. These cut-outs are for clipping the mechanical connector 10 onto the windscreen wiper during assembly thereof.

The element 4 forming a spline is generally made of metal and may be referred to hereinafter by the shorter term <<spline>>. This spline has an essential function in this windscreen wiper since it confers on the windscreen wiper as a whole the required stiffness for good mechanical strength for correct distribution of the force with which the windscreen wiper bears on a window at the same time as remaining sufficiently flexible to adapt to the shape of the surface of the window, which generally has a domed shape.

If this flexible windscreen wiper is raised, it assumes the shape of a bean such that its lower face is concave and its upper face consequently convex.

In this windscreen wiper with a heating device, the spline 4 also has the function of channelling and distributing the heat coming from the heating element 13 disposed on its upper face. Consequently, in a windscreen wiper with a heating device, it is important that the spline is made from a material that is a good conductor of heat so as to form an active part of the heating device.

The heating element 13 is in this example of a known windscreen wiper in the form of a resistive film fixed to the upper face of the element 4 forming a spline disposed in the housing 5 of the support element 3. The housing 5 is open upwardly over all its length via a wide longitudinal slot 17 in which this resistive film extends. Consequently, the lateral zones of the upper face of the spline are not covered by this resistive film.

Electrical contact points 18 provided on the resistive film immediately under the mechanical connector are connected to the electrical connector 12 by way of electrically conducive means that in the example shown include conductive wires 19 that pass through the slot 17 of the housing 5.

It is possible to use instead of the conductive wires 19 a leadframe or flexible contact shoes.

An object of the invention is to propose a heating device for a windscreen wiper of the same kind in which the heating element is better protected than in the windscreen wiper that has just been described, while its placement is the optimum for the distribution of heat to the lower face of the support element and toward the wiper blade, at the same time as providing a simple way to connect the heating element to the electrical connector integrated into the mechanical connector for the connection to the actuating arm.

This latter aspect is particularly difficult to implement, given that the width of the spline 4 is relatively limited, of the order of a 8 to 10 mm, and that it is desirable to avoid providing a relatively large hole in the core of the spline in order not to reduce the strength of the spline and not to impact on the distribution of pressure when the windscreen wiper is operating.

In accordance with the invention, the heating element is disposed so that the elements in the mechanical connector are not directly exposed to the heat emitted by the heating element, at the same time as providing a simple connection between the heating element and the electrical connector that is associated with the mechanical connector.

This reduces the risk of excessive heat damaging the elements in the mechanical connector, including the electrical connector, if the heating device is used frequently.

The invention consists in a heating device adapted to be assembled to a support element of a windscreen wiper, the heating device including:
at least one element having a longitudinal main axis and adapted to be mounted inside a longitudinal housing of the support element so as to form a spline, said housing being open above said spline via of a longitudinal slot;
at least one heating element disposed on the element forming a spline and connected by electrically conductive means to an electrical connector disposed on a so-called upper face thereof;
   characterized in that the heating element is disposed on a so-called lower face of the element forming a spline and in that said electrically conductive means pass from said lower face to said upper face around the element forming a spline at one of the ends thereof.

In accordance with other features of the invention:
said electrically conductive means extend along said slot on said upper face of the element forming a spline;
said electrically conductive means are connected to the heating element via contact shoes disposed in an end zone on said lower face of the element forming a spline;
said end zone is centrally placed;
said contact shoes are buried in a resin for sealing them; and
the heating element is a resistive film fixed to said lower face of the element forming a spline and extending to the vicinity of the end thereof at which said electrically conductive means pass around it.

Another aim of the invention is to propose a windscreen wiper including such a heating device.

A further aim of the invention is to propose a method of assembling such a windscreen wiper.

Other features and advantages of the invention will emerge from the following nonlimiting description of an embodiment of the invention with reference to the appended figures, in which:

FIG. 1, already described, is an exploded view of a prior art windscreen wiper;

FIG. 2, already described, is a sectional view of the windscreen wiper from FIG. 1, after assembly, the heating element being placed on the upper face of the spline;

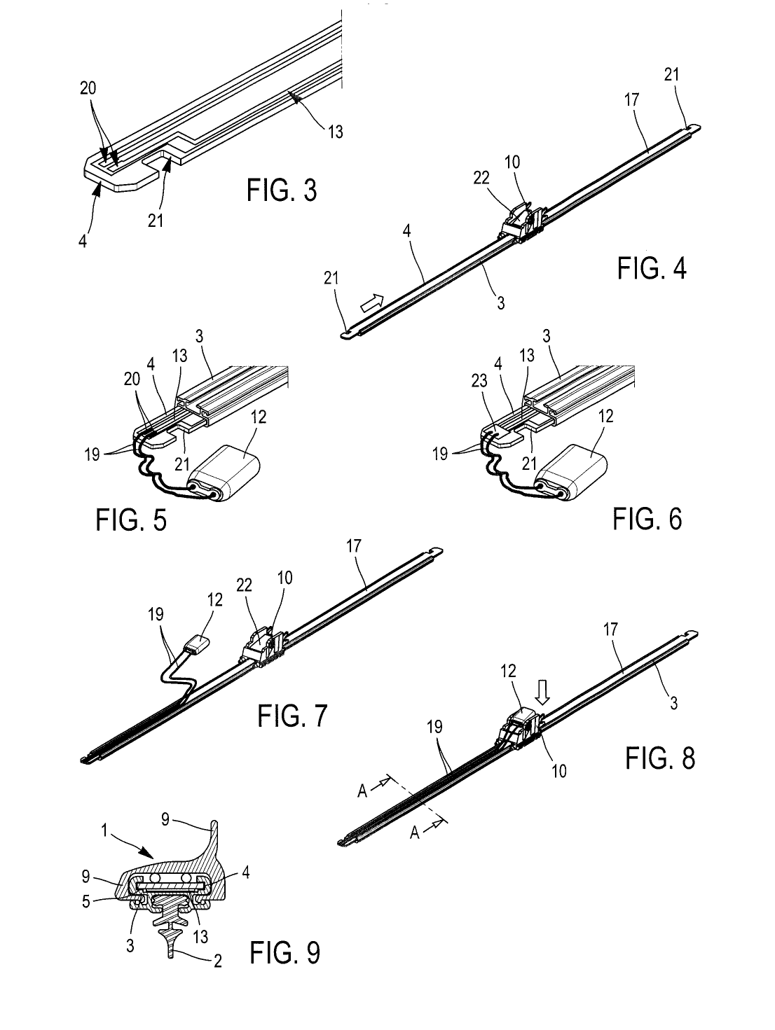

FIG. 3 is a partial perspective view of the lower face of a spline showing diagrammatically a heating element fixed to the lower face thereof, as well as contact shoes connected to the heating element;

FIG. 4 is a perspective view showing diagrammatically the insertion of the spline carrying the heating element into a longitudinal housing of a support element;

FIG. 5 is a partial perspective view showing one end of the spline projecting from the support element and carrying contact shoes for connecting the heating element to an electrical connector via conductive wires;

FIG. 6 is a partial perspective view corresponding to FIG. 5, in which the contact shoes have been buried in a sealing resin;

FIG. 7 shows diagrammatically how the conductive wires pass around the end of the spline and are disposed in a slot of the support element, on the upper face of the spline;

FIG. 8 shows diagrammatically the conductive wires disposed in the slot of the support element and the electrical connector placed on a mechanical connector fixed to the support element into which the spline is inserted;

FIG. 9 is a cross-section taken along the line A-A in FIG. 8;

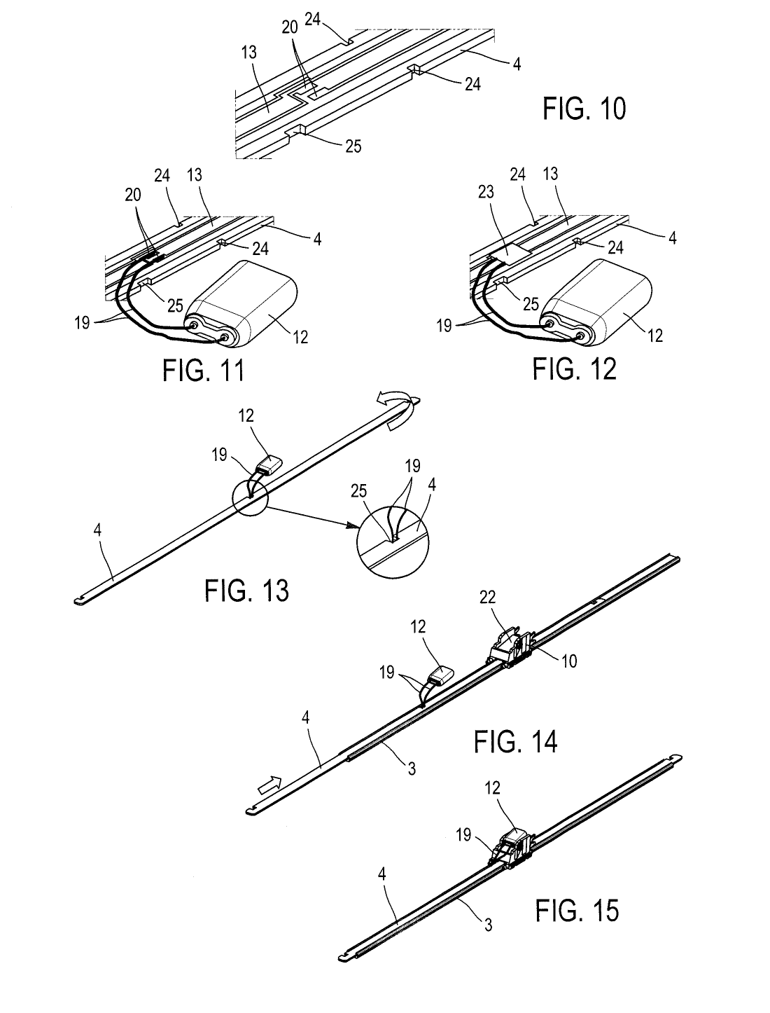

FIG. 10 is a partial perspective view of the central part of the lower face of a spline showing a heating element disposed on the lower face of the spline that includes a lateral notch offset longitudinally relative to the centre and intended to be used for passing conductive wires from the lower face to the upper face of the spline;

FIG. 11 is a partial perspective view of the central part of the spline from FIG. 10, showing the conductive wires connected on the one hand to contact shoes associated with the heating element and on the other hand to an electrical connector;

FIG. 12 is a partial perspective view corresponding to FIG. 11, in which the contact shoes have been buried in a sealing resin;

FIG. 13 shows diagrammatically the conductive wires extending from the lower face to the upper face of the spline via a lateral notch longitudinally offset therefrom;

FIG. 14 is a perspective view showing diagrammatically the insertion of the spline with the heating element into a longitudinal housing of a support element; and

FIG. 15 shows dogmatically the conductive wires passing through the offset notch and connected to the electrical connector placed on a mechanical connector fixed to the support element.

In the figures, the elements identical or equivalent to those already described with reference to FIGS. 1 and 2 will bear the same reference signs.

The essential difference relative to the heating device of the windscreen wiper already described with reference to FIGS. 1 and 2 resides in the fact that the heating element 13 is disposed underneath the element 4 forming the spline and not on top of the latter. This gives the advantages of improved downward dispensing and distribution of the heat emitted by the heating element at the same time as protecting the electrical connector 12 from direct heat radiation that could cause overheating of the connector in the event of prolonged use.

The heating element 13 is advantageously formed by a resistive film that will be well protected in the housing 5 provided in the support element 3. Of course, this does not exclude the use of resistive wires with the same arrangement instead of the resistive film.

As the heating element it is equally possible to use a resistive coating in the form of a resistive paint or other coating deposited on the spline 4.

Now, with this advantageous location of the heating element 13, there is a connection problem at the level of the electrical connection between the heating element 13 that is under the spline 4 and the electrical connector 12 that is on top of it.

In accordance with the invention, this connection problem is solved by virtue of the fact that the electrically conductive means such as the conductive wires 19, or other electrically conducive means, connecting the heating element 13 to the electrical connector 12 pass from the lower face to the upper face of the spline 4 around the latter on one side thereof, and in particular at one of its ends.

This avoids weakening the spline by making a hole in it, especially as the width of the spline is relatively limited, of the order of 8 to 10 mm.

The invention will now be described in detail with reference to the drawings.

FIG. 3 shows part of the lower face of a spline 4 onto which has been fixed a heating element 13 in the form of a resistive film. This resistive film advantageously extends to the vicinity of the end of the spline at which the electrically conductive means 19 pass around it.

The resistive film 13 has two connection points in the form of contact shoes 20 disposed parallel to each other in an end zone of the lower face of the spline. This end zone is centrally placed at the end of the spline 4.

Furthermore, the spline 4 has at its ends a lateral notch 21 for clipping on a respective cap 7 (see FIG. 1). In the example shown the contact shoes 20 are disposed after the notch 21, but they could instead be disposed before the latter.

FIG. 4 shows the spline 4 from FIG. 3 placed inside the housing 5 of the support element 3. The ends of the spline project from the ends of the support element 3 to expose the lateral notches 21 for fixing the caps 7.

Moreover, a mechanical connector 10 is clipped to the centre of the support element 3. This mechanical connector 10 has on its upper face a housing 22 for receiving an electrical connector 12 (see FIG. 4), as shown in FIG. 8. To carry out the assembly, the element 4 forming a spline is then inserted into the housing 5 of the support element 3, after which it passes to the centre of the wiper 1 in rail shapes in the mechanical connector 10 with the aid of notches 24 that come into corresponding relationship with nipples (not represented) provided in the mechanical connector 10. The housing 22 will thereafter be closed by the cap 14 shown in FIG. 1.

The heating element 13 is connected to the electrical connector 12 by electrically conductive means in the form of conductive wires 19. In the example shown in FIG. 5, one of the ends of each conductive wire 19 is soldered to a respective shoe 20 in the end zone of the spline 4, while its opposite end is fixed to the electrical connector 12.

FIG. 6 shows diagrammatically that the contact shoes 20 from FIG. 5 are buried in a resin 23 so as to protect the shoes by sealing them.

The invention also consists in a method of assembling a windscreen wiper including the heating device in accordance with the invention.

The assembly method in accordance with the invention includes the following phases:
the heating element 13 is disposed along a lower face of the spline 4 and the heating element is fixed to the lower face;
the spline 4 is inserted with the heating element 13 into a longitudinal housing 5 provided on a support element 3, the length of the latter being matched to that of the spline 4 so that the ends of the latter project out of the housing 5;
the electrically conductive means 19 are fixed to one of the ends of the heating element 13 to connect the latter to an electrical connector 12;
the electrically conductive means 19 are passed from the lower face to the upper face of the spline around the end of the spline;
the electrically conductive means 19 are positioned in the longitudinal slot 17 of the upper face of the support element 3 that is open upwardly (see FIG. 7) and the electrical connector 12 is fixed to a mechanical connector 10 disposed substantially in the middle of the support element 3 (see FIG. 8);
a cover element 6 is fixed on either side of the mechanical connector 10;
a wiper blade 2 is placed in a groove of the support element 3; and
end caps 7 are fixed to respective ends of the assembly formed by the support element 3, the spline 4 and the cover elements 6.

In accordance with another feature of the method in accordance with the invention, the electrically conductive means 19 are fixed to contact shoes 20 provided at said end of the heating element.

In accordance with a further feature of the method in accordance with the invention, the electrically conductive means 19 are also connected to the electrical connector 12 before passing them around one of the ends of the spline 4.

FIGS. 10 to 15 show an embodiment of the heating device enabling the conductive wires 19 to be passed around one of the lateral sides of the spline 4, again to avoid making holes in the core thereof.

FIG. 10 shows the central part of the lower face of a spline 4 provided with a heating element 13 in the form of a resistive film adhesively bonded to this face. The spline includes two opposite central notches 24 disposed on the lateral sides of the spline for fixing the mechanical connector 10. It is further provided with a lateral notch 25 that is offset in the longitudinal direction relative to the centre of the support element 3 where the mechanical connector 10 is fixed so as to be juxtaposed to the latter when the spline 4 has been inserted by sliding it into the housing 5 of the support element (see FIGS. 14 and 15).

The offset notch 25 is sufficiently deep on the one hand to receive the conductive wires 19 and on the other hand to ensure that the latter do not impede the insertion of the spline 4 into the support element 3.

The heating element 13 is provided with contact shoes 20 which in this case are disposed relatively near the offset notch 25.

One of the ends of the conductive wires 19 is advantageously soldered to a respective shoe 20 before the spline 4 is inserted by sliding it into the housing 5 of the support element. The other end of the conductive wires 19 is already connected to the electrical connector 12. The mechanical connector 10 is first mounted on the support element 3 and thereafter the spline 4 is inserted into the housing 5 and the electrical connector 12 is placed in the housing 22 provided on the mechanical connector 10, it remaining only to assemble the wiper blade 2, the two cover elements 6 and the caps 7, as well as the cap 14 that caps the mechanical connector 10.

The invention further consists in a windscreen wiper including the heating device in accordance with the invention. This windscreen wiper is advantageously part of a wiping device used on a vehicle.

Of course, the invention is not limited to the examples shown and described, and the person skilled in the art will be in a position to arrive at variants without this departing from the scope of the invention, in particular variants in which resistive wires or a resistive coating are or is used instead of the resistive film.

It should in particular be noted that the windscreen wiper with a heating device in accordance with the invention may also have no device for distributing a washing liquid or, to the contrary, be provided with a duplicated distribution device, one on each lateral side of the wiper. The presence of an aerodynamic deflector is not essential to the implementation of the invention either.

1. A heating device adapted to be assembled to a support element of a windscreen wiper, the heating device comprising:
at least one element having a longitudinal main axis and adapted to be mounted inside a longitudinal housing of the support element so as to form a spline, said housing being open above said spline via a longitudinal slot;
at least one heating element disposed on the element forming a spline and connected by electrically conductive means to an electrical connector disposed on a so-called upper face thereof;
wherein the heating element is disposed on a so-called lower face of the element forming a spline and in that said electrically conductive means pass from said lower face to said upper face around the element forming a spline at one of the ends thereof.

2. The heating device according to claim 1, wherein said electrically conductive means extend along said slot on said upper face of the element forming a spline.

3. The heating device according to claim 1, wherein said electrically conductive means are connected to the heating element via contact shoes disposed in an end zone on said lower face of the element forming a spline.

4. The heating device according to claim 3, wherein said end zone is centrally placed.

5. The heating device according to claim 3, wherein said contact shoes are buried in a resin for sealing them.

6. The heating device according to claim 1, wherein the heating element is a resistive film fixed to said lower face of the element forming a spline and extending to the vicinity of the end thereof at which said electrically conductive means pass round it.

7. A windscreen wiper, comprising:
a heating device according to claim 1; and
a support element having a longitudinal main axis that includes:
a longitudinal housing, and
means for retaining a wiper blade;
a wiper blade; and
a mechanical connector adapted to connect the windscreen wiper to an actuating arm of a wiping device, this mechanical connector being mounted on the support element into which is inserted an element forming a spline.

8. A method of assembling a windscreen wiper according to claim 7, comprising:
disposing a heating element along a lower face of an element forming a spline and the heating element is fixed to said lower face;
inserting the element forming the spline with the heating element into a longitudinal housing provided on a support element, the length of the latter being matched to that of the element forming a spline so that the ends of the latter project out of said housing;
fixing electrically conductive means to one of the ends of the heating element to connect the latter to an electrical connector;
passing the electrically conductive means from said lower face to an upper face of said element forming a spline around said end of the element forming a spline;
positioning the electrically conductive means in a longitudinal slot of said upper face of the support element open upwardly and the electrical connector is switched to a mechanical connector disposed substantially in the middle of the support element;
fixing a cover element on either side of the mechanical connector;
placing a wiper blade in a groove of the support element; and
fixing end caps to respective ends of the assembly formed by the support element, the element forming a spline and the cover elements.

9. The method according to claim 8, wherein the electrically conductive means are fixed to contact shoes provided at said end of the heating element.

10. The method according to claim 8, wherein the electrically conductive means are connected to the electrical connector before passing them around one of the ends of the element forming a spline.
